(19) United States
(12) Patent Application Publication
(10) Pub. No.: US 2009/0233004 A1
(43) Pub. Date: Sep. 17, 2009

(54) METHOD AND SYSTEM FOR DEPOSITING SILICON CARBIDE FILM USING A GAS CLUSTER ION BEAM

(75) Inventors: Steven Sherman, Newton, MA (US); John J. Hautala, Beverly, MA (US); Noel Russell, Waterford, NY (US); Martin D. Tabat, Nashua, NH (US); Thomas G. Tetreault, Manchester, NH (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TEL EPION INC., Billerica, MA (US)

(21) Appl. No.: 12/049,583

(22) Filed: Mar. 17, 2008

(51) Int. Cl. C23C 14/14

(52) U.S. Cl. 427/527

(57) ABSTRACT

A method for depositing material on a substrate is described. The method comprises maintaining a reduced-pressure environment around a substrate holder for holding a substrate having a surface, and holding the substrate securely within the reduced-pressure environment. Additionally, the method comprises forming a gas cluster ion beam (GCIB) from a pressurized gas comprising a compound having silicon (Si) and carbon (C), accelerating the GCIB to the reduced-pressure environment, and irradiating the accelerated GCIB onto at least a portion of the surface of the substrate to form a thin film containing silicon and carbon, wherein the carbon content is greater than or equal to about 10%. Further the compound may possess a Si—C bond.

### CROSS-REFERENCE TO RELATED APPLICATIONS

This application is related to pending U.S. patent application Ser. No. 11/864,330, entitled “METHOD FOR DIRECTIONAL DEPOSITION USING A GAS CLUSTER ION BEAM” (EP-121), filed on Sep. 28, 2007; and pending U.S. patent application Ser. No. 11/864,961, entitled “METHOD FOR DEPOSITING FILMS USING GAS CLUSTER ION BEAM PROCESSING” (EP-142), filed on Sep. 29, 2007. The entire content of these applications is herein incorporated by reference in its entirety.

### BACKGROUND OF THE INVENTION

1. Field of the Invention

The invention relates to a method for performing thin film deposition using a gas cluster ion beam (GCIB), and more particularly to a method for depositing silicon carbide-containing films on a substrate using a GCIB.

2. Description of Related Art

Gas-cluster ion beams (GCIB's) are used for etching, cleaning, smoothing, and forming thin films. For purposes of this discussion, gas clusters are nano-sized aggregates of materials that are gaseous under conditions of standard temperature and pressure. Such gas clusters may consist of aggregates including a few to several thousand molecules, or more, that are loosely bound together. The gas clusters can be ionized by electron bombardment, which permits the gas clusters to be formed into directed beams of controllable energy. Such cluster ions each typically carry positive charges given by the product of the magnitude of the electronic charge and an integer greater than or equal to one that represents the charge state of the cluster ion.

The larger sized cluster ions are often the most useful because of their ability to carry substantial energy per cluster ion, while yet having only modest energy per individual molecule. The ion clusters disintegrate on impact with the substrate. Each individual molecule in a particular disintegrated ion cluster carries only a small fraction of the total cluster energy. Consequently, the impact effects of large ion clusters are substantial, but are limited to a very shallow surface region. This makes gas cluster ions effective for a variety of surface modification processes, but without the tendency to produce deeper sub-surface damage that is characteristic of conventional ion beam processing.

Conventional cluster ion sources produce cluster ions having a wide size distribution scaling with the number of molecules in each cluster that may reach several thousand molecules). Clusters of atoms can be formed by the condensation of individual gas atoms (or molecules) during the adiabatic expansion of high pressure gas from a nozzle into a vacuum. A skimmer with a small aperture strips divergent streams from the core of this expanding gas flow to produce a collimated beam of clusters. Neutral clusters of various sizes are produced and held together by weak inter-atomic forces known as Van der Waals forces. This method has been used to produce beams of clusters from a variety of gases, such as helium, neon, argon, krypton, xenon, nitrogen, oxygen, carbon dioxide, sulfur hexafluoride, nitric oxide, nitrous oxide, and mixtures of these gases.

Several emerging applications for GCIB processing of substrates on an industrial scale are in the semiconductor field. Although GCIB processing of a substrate is performed using a wide variety of gas-cluster source gases, many of which are inert gases, many semiconductor processing applications use reactive source gases, sometimes in combination or mixture with inert or noble gases, to form the GCIB.

### SUMMARY OF THE INVENTION

The invention relates to a method for performing thin film deposition using a gas cluster ion beam (GCIB).

The invention further relates to a method for depositing silicon carbide-containing films on a substrate using a GCIB.

According to one embodiment, a method of, and computer readable medium for, depositing material on a substrate is described. The method comprises maintaining a reduced-pressure environment around a substrate holder for holding a substrate having a surface, and holding the substrate securely within the reduced-pressure environment. Additionally, the method comprises forming a gas cluster ion beam (GCIB) from a pressurized gas comprising a compound having silicon (Si) and carbon (C), accelerating the GCIB to the reduced-pressure environment, and irradiating the accelerated GCIB onto at least a portion of the surface of the substrate to form a thin film containing silicon and carbon, wherein the carbon content is greater than or equal to 10%. Further, the compound may possess a Si—C bond.

### BRIEF DESCRIPTION OF THE DRAWINGS

In the accompanying drawings:

FIG. 1 is an illustration of a GCIB processing system;

FIG. 2 is another illustration of a GCIB processing system;

FIG. 3 is an illustration of an ionization source for a GCIB processing system; and

FIG. 4 illustrates a method of depositing material on a substrate according to an embodiment.

### DETAILED DESCRIPTION OF SEVERAL EMBODIMENTS

A method and system for performing material infusion into a substrate using a gas cluster ion beam (GCIB) is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

In the description and claims, the terms “coupled” and “connected,” along with their derivatives, are used. It should be understood that these terms are not intended as synonyms for each other. Rather, in particular embodiments, “connected” may be used to indicate that two or more elements are in direct physical or electrical contact with each other while “coupled” may further mean that two or more elements are not in direct contact with each other, but yet still co-operate or interact with each other.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

As described above, there is a general need for depositing material on a surface of a substrate using a GCIB, as well as selectively depositing material on only chosen surfaces of a substrate using a GCIB. By adjusting the orientation of the substrate relative to the GCIB, material deposition can proceed on surfaces that are substantially perpendicular to the incident GCIB while material deposition can be avoided or reduced on surfaces that are substantially parallel with the incident GCIB. Moreover, one or more properties of the GCIB, including the beam composition, can be adjusted or alternated in order to directionally deposit successive material films having differing properties from one layer to an adjacent layer.

Furthermore, there exists a growing need for depositing silicon carbide-containing films on a substrate. However, the inventors have recognized that conventional gas mixtures for depositing silicon carbide on a substrate produce low carbon content silicon carbide-containing films. For example, silane (SiH₄) with methane (CH₄) or ethane (C₂H₆) have been found to produce low carbon content silicon carbide-containing films (e.g., ˜5% C).

Therefore, according to one embodiment, a method of depositing material on a substrate is described. The method comprises maintaining a reduced-pressure environment around a substrate holder for holding a substrate having a surface, and holding the substrate securely within the reduced-pressure environment. Additionally, the method comprises forming a gas cluster ion beam (GCIB) from a pressurized gas comprising a compound having silicon (Si) and carbon (C), accelerating the GCIB to the reduced-pressure environment, and irradiating the accelerated GCIB onto at least a portion of the surface of the substrate to form a thin film containing silicon and carbon, wherein the carbon content is greater than or equal to 10%. Further, the compound may possess a Si—C bond.

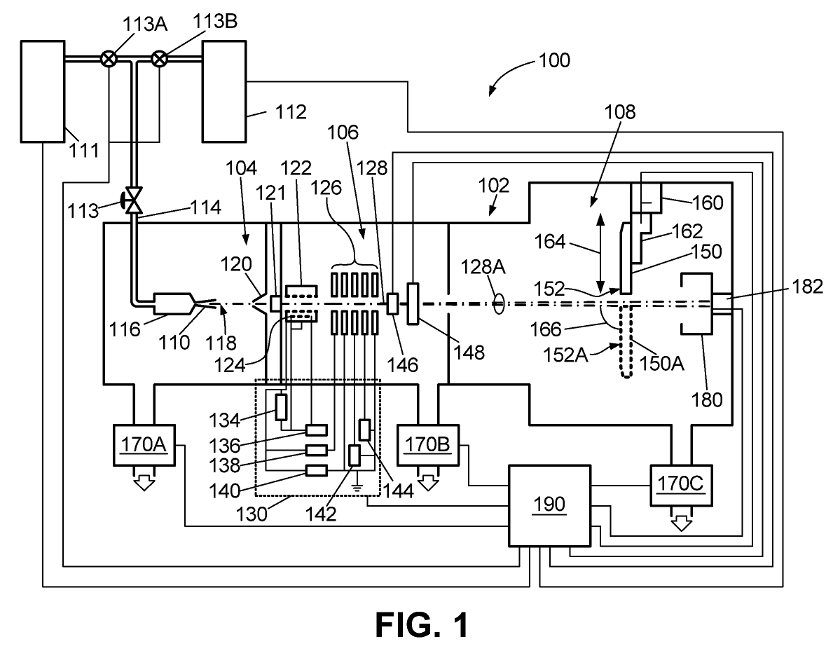

According to an embodiment, a GCIB processing system 100 is depicted in FIG. 1 comprising a vacuum vessel 102, substrate holder 150, upon which a substrate 152 to be processed is affixed and around which a reduced-pressure environment is maintained during substrate processing, and vacuum pumping systems 170A, 170B, and 170C. Substrate 152 can be a semiconductor substrate, a wafer, a flat panel display (FPD), a liquid crystal display (LCD), or any other workpiece. GCIB processing system 100 is configured to produce a GCIB for treating substrate 152.

Referring still to GCIB processing system 100 in FIG. 1, the vacuum vessel 102 comprises three communicating chambers, namely, a source chamber 104, an ionization/acceleration chamber 106, and a processing chamber 108 to provide a reduced-pressure enclosure. The three chambers are evacuated to suitable operating pressures by vacuum pumping systems 170A, 170B, and 170C, respectively. In the three communicating chambers 104, 106, 108, a gas cluster beam can be formed in the first chamber (source chamber 104), while a gas cluster ion beam can be formed in the second chamber (ionization/acceleration chamber 106) wherein the gas cluster beam is ionized and accelerated, and then in the third chamber (processing chamber 108) the accelerated gas cluster ion beam may be utilized to treat substrate 152.

As shown in FIG. 1, GCIB processing system 100 can comprise one or more gas sources configured to introduce one or more gases or mixture of gases to vacuum vessel 102. For example, a first gas composition stored in a first gas source 111 is admitted under pressure through a first gas control valve 113A to a gas metering valve or valves 113. Additionally, for example, a second gas composition stored in a second gas source 112 is admitted under pressure through a second gas control valve 113B to the gas metering valve or valves 113. Furthermore, for example, the first gas composition or the second gas composition or both can comprise a film forming gas composition. Further yet, for example, the first gas composition or second gas composition or both can include a condensable inert gas, carrier gas or dilution gas. For example, the inert gas, carrier gas or dilution gas can include a noble gas, i.e., He, Ne, Ar, Kr, Xe, or Rn.

Furthermore, the first gas source 111 and the second gas source 112 may be utilized either alone or in combination with one another to produce ionized clusters. The film forming composition can comprise a film precursor or precursors that include the principal atomic or molecular species of the film desired to be produced on the substrate. Additionally, the film forming composition can include a reducing agent that assists with the reduction of a film precursor on a substrate. For instance, the reducing agent or agents may react with a part of or all of a film precursor on the substrate. Additionally yet, the film forming composition can include a polymerizing agent that may assist with the polymerization of a film precursor on the substrate.

The high pressure, condensable gas comprising the first gas composition or the second gas composition or both is introduced through gas feed tube 114 into stagnation chamber 116 and is ejected into the substantially lower pressure vacuum through a properly shaped nozzle 110. As a result of the expansion of the high pressure, condensable gas from the stagnation chamber 116 to the lower pressure region of the source chamber 104, the gas velocity accelerates to supersonic speeds and gas cluster beam 118 emanates from nozzle 110.

The inherent cooling of the jet as static enthalpy is exchanged for kinetic energy, which results from the expansion in the jet, causes a portion of the gas jet to condense and form a gas cluster beam 118 having clusters, each consisting of from several to several thousand weakly bound atoms or molecules. A gas skimmer 120, positioned downstream from the exit of the nozzle 110 between the source chamber 104 and ionization/acceleration chamber 106, partially separates the gas molecules on the peripheral edge of the gas cluster beam 118, that may not have condensed into a cluster, from the gas molecules in the core of the gas cluster beam 118, that may have formed clusters. Among other reasons, this selection of a portion of gas cluster beam 118 can lead to a reduction in the pressure in the downstream regions where higher pressures may be detrimental (e.g., ionizer 122, and processing chamber 108). Furthermore, gas skimmer 120 defines an initial dimension for the gas cluster beam entering the ionization/acceleration chamber 106.

After the gas cluster beam 118 has been formed in the source chamber 104, the constituent gas clusters in gas cluster beam 118 are ionized by ionizer 122 to form GCIB 128. The ionizer 122 may include an electron impact ionizer that produces electrons from one or more filaments 124, which are accelerated and directed to collide with the gas clusters in the gas cluster beam 118 inside the ionization/acceleration chamber 106. Upon collisional impact with the gas cluster, electrons of sufficient energy eject electrons from molecules in the gas clusters to generate ionized molecules. The ionization of gas clusters can lead to a population of charged gas cluster ions, generally having a net positive charge.

As shown in FIG. 1, beam electronics 130 are utilized to ionize, extract, accelerate, and focus the GCIB 128. The beam electronics 130 include a filament power supply 136 that provides voltage V_{F} to heat the ionizer filament 124.

Additionally, the beam electronics 130 include a set of suitably biased high voltage electrodes 126 in the ionization/acceleration chamber 106 that extracts the cluster ions from the ionizer 122. The high voltage electrodes 126 then accelerate the extracted cluster ions to a desired energy and focus them to define GCIB 128. The kinetic energy of the cluster ions in GCIB 128 typically ranges from about 1000 electron volts (1 keV) to several tens of keV. For example, GCIB 128 can be accelerated to 1 to 70 keV.

As illustrated in FIG. 1, the beam electronics 130 further include an anode power supply 134 that provides voltage V_{A} to an anode of ionizer 122 for accelerating electrons emitted from filament 124 and causing the electrons to bombard the gas clusters in gas cluster beam 118, which produces cluster ions.

Additionally, as illustrated in FIG. 1, the beam electronics 130 include an extraction power supply 138 that provides voltage V_{E} to bias at least one of the high voltage electrodes 126 to extract ions from the ionizing region of ionizer 122 and to form the GCIB 128. For example, extraction power supply 138 provides a voltage to a first electrode of the high voltage electrodes 126 that is less than or equal to the anode voltage of ionizer 122.

Furthermore, the beam electronics 130 can include an accelerator power supply 140 that provides voltage V_{Acc} to bias one of the high voltage electrodes 126 with respect to the ionizer 122 so as to result in a total GCIB acceleration energy equal to about V_{Acc} electron volts (eV). For example, accelerator power supply 140 provides a voltage to a second electrode of the high voltage electrodes 126 that is less than or equal to the anode voltage of ionizer 122 and the extraction voltage of the first electrode.

Further yet, the beam electronics 130 can include lens power supplies 142, 144 that may be provided to bias some of the high voltage electrodes 126 with potentials (e.g., V_{L1} and V_{L2}) to focus the GCIB 128. For example, lens power supply 142 can provide a voltage to a third electrode of the high voltage electrodes 126 that is less than or equal to the anode voltage of ionizer 122, the extraction voltage of the first electrode, and the accelerator voltage of the second electrode, and lens power supply 144 can provide a voltage to a fourth electrode of the high voltage electrodes 126 that is less than or equal to the anode voltage of ionizer 122, the extraction voltage of the first electrode, the accelerator voltage of the second electrode, and the first lens voltage of the third electrode.

Note that many variants on both the ionization and extraction schemes may be used. While the scheme described here is useful for purposes of instruction, another extraction scheme involves placing the ionizer and the first element of the extraction electrode(s) (or extraction optics) at V_{acc}. This typically requires fiber optic programming of control voltages for the ionizer power supply, but creates a simpler overall optics train. The invention described herein is useful regardless of the details of the ionizer and extraction lens biasing.

A beam filter 146 in the ionization/acceleration chamber 106 downstream of the high voltage electrodes 126 can be utilized to eliminate monomers, or monomers and light cluster ions from the GCIB 128 to define a filtered process GCIB 128A that enters the processing chamber 108. In one embodiment, the beam filter 146 substantially reduces the number of clusters having 100 or less atoms or molecules or both. The beam filter may comprise a magnet assembly for imposing a magnetic field across the GCIB 128 to aid in the filtering process.

Referring still to FIG. 1, a beam gate 148 is disposed in the path of GCIB 128 in the ionization/acceleration chamber 106. Beam gate 148 has an open state in which the GCIB 128 is permitted to pass from the ionization/acceleration chamber 106 to the processing chamber 108 to define process GCIB 128A, and a closed state in which the GCIB 128 is blocked from entering the processing chamber 108. A control cable conducts control signals from control system 190 to beam gate 148. The control signals controllably switch beam gate 148 between the open or closed states.

The process GCIB 128A is accelerated from the ionization/acceleration chamber 106 into the reduced-pressure environment around the substrate holder 150 in processing chamber 108. A substrate 152, which may be a wafer or semiconductor wafer, a flat panel display (FPD), a liquid crystal display (LCD), or other substrate to be processed by GCIB processing, is held securely within the reduced-pressure environment and is disposed in the path of the process GCIB 128A in the processing chamber 108. Because most applications contemplate the processing of large substrates with spatially uniform results, a scanning system may be desirable to uniformly scan the process GCIB 128A across large areas to produce spatially homogeneous results.

An X-scan actuator 160 provides linear motion of the substrate holder 150 in the direction of X-scan motion (into and out of the plane of the paper). A Y-scan actuator 162 provides linear motion of the substrate holder 150 in the direction of Y-scan motion 164, which is typically orthogonal to the X-scan motion. The combination of X-scanning and Y-scanning motions translates the substrate 152, held by the substrate holder 150, in a raster-like scanning motion through process GCIB 128A to cause a uniform (or otherwise programmed) irradiation of a surface of the substrate 152 by the process GCIB 128A for processing of the substrate 152.

The substrate holder 150 disposes the substrate 152 at an angle with respect to the axis of the process GCIB 128A so that the process GCIB 128A has an angle of beam incidence 166 with respect to a substrate 152 surface. The angle of beam incidence 166 may be 90 degrees or some other angle, but is typically 90 degrees or near 90 degrees. During Y-scanning, the substrate 152 and the substrate holder 150 move from the shown position to the alternate position “A” indicated by the designators 152A and 150A, respectively. Notice that in moving between the two positions, the substrate 152 is scanned through the process GCIB 128A, and in both extreme positions, is moved completely out of the path of the process GCIB 128A (over-scanned). Though not shown explicitly in FIG. 1, similar scanning and over-scan is performed in the (typically) orthogonal X-scan motion direction (in and out of the plane of the paper).

A beam current sensor 180 may be disposed beyond the substrate holder 150 in the path of the process GCIB 128A so as to intercept a sample of the process GCIB 128A when the substrate holder 150 is scanned out of the path of the process GCIB 128A. The beam current sensor 180 is typically a faraday cup or the like, closed except for a beam-entry opening, and is typically affixed to the wall of the vacuum vessel 102 with an electrically insulating mount 182.

As shown in FIG. 1, control system 190 connects to the X-scan actuator 160 and the Y-scan actuator 162 through electrical cable and controls the X-scan actuator 160 and the Y-scan actuator 162 in order to place the substrate 152 into or out of the process GCIB 128A and to scan the substrate 152 uniformly relative to the process GCIB 128A to achieve desired processing of the substrate 152 by the process GCIB 128A. Control system 190 receives the sampled beam current collected by the beam current sensor 180 by way of an electrical cable and, thereby, monitors the GCIB and controls the GCIB dose received by the substrate 152 by removing the substrate 152 from the process GCIB 128A when a predetermined dose has been delivered.

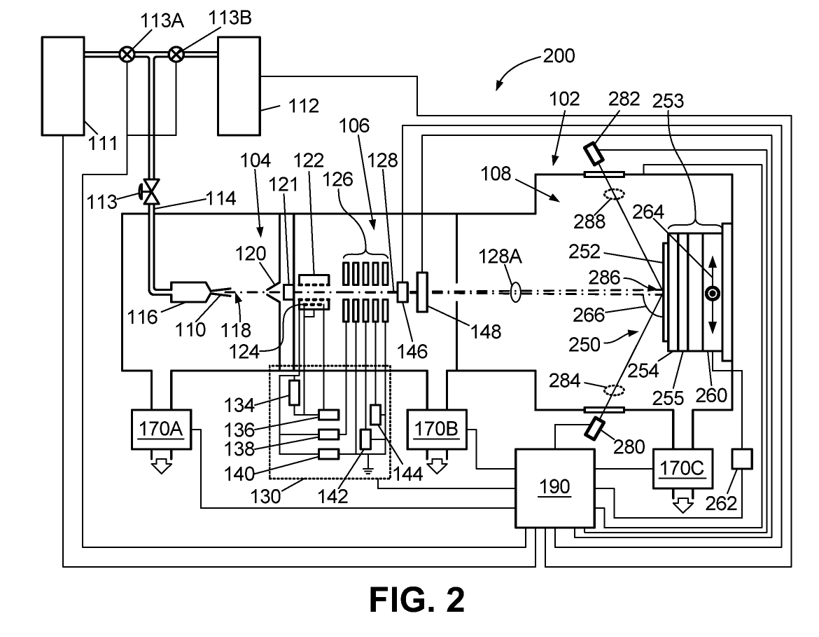

In the embodiment shown in FIG. 2, the GCIB processing system 200 can be similar to the embodiment of FIG. 1 and further comprise a X-Y positioning table 253 operable to hold and move a substrate 252 in two axes, effectively scanning the substrate 252 relative to the process GCIB 128A. For example, the X-motion can include motion into and out of the plane of the paper, and the Y-motion can include motion along direction 264.

The process GCIB 128A impacts the substrate 252 at a projected impact region 286 on a surface of the substrate 252, and at an angle of beam incidence 266 with respect to the substrate 252 surface. By X-Y motion, the X-Y positioning table 253 can position each portion of a surface of the substrate 252 in the path of process GCIB 128A so that every region of the surface may be made to coincide with the projected impact region 286 for processing by the process GCIB 128A. An X-Y controller 262 provides electrical signals to the X-Y positioning table 253 through an electrical cable for controlling the position and velocity in each of X-axis and Y-axis directions. The X-Y controller 262 receives control signals from, and is operable by, control system 190 through an electrical cable. X-Y positioning table 253 moves by continuous motion or by stepwise motion according to conventional X-Y table positioning technology to position different regions of the substrate 252 within the projected impact region 286. In one embodiment, X-Y positioning table 253 is programmably operable by the control system 190 to scan, with programmable velocity, any portion of the substrate 252 through the projected impact region 286 for GCIB processing by the process GCIB 128A.

The substrate holding surface 254 of positioning table 253 is electrically conductive and is connected to a dosimetry processor operated by control system 190. An electrically insulating layer 255 of positioning table 253 isolates the substrate 252 and substrate holding surface 254 from the base portion 260 of the positioning table 253. Electrical charge induced in the substrate 252 by the impinging process GCIB 128A is conducted through substrate 252 and substrate holding surface 254, and a signal is coupled through the positioning table 253 to control system 190 for dosimetry measurement. Dosimetry measurement has integrating means for integrating the GCIB current to determine a GCIB processing dose. Under certain circumstances, a target-neutralizing source (not shown) of electrons, sometimes referred to as electron flood, may be used to neutralize the process GCIB 128A. In such case, a Faraday cup (not shown) may be used to assure accurate dosimetry despite the added source of electrical charge, the reason being that typical Faraday cups allow only the high energy positive ions to enter and be measured.

In operation, the control system 190 signals the opening of the beam gate 148 to irradiate the substrate 252 with the process GCIB 128A. The control system 190 monitors measurements of the GCIB current collected by the substrate 252 in order to compute the accumulated dose received by the substrate 252. When the dose received by the substrate 252 reaches a predetermined dose, the control system 190 closes the beam gate 148 and processing of the substrate 252 is complete. Based upon measurements of the GCIB dose received for a given area of the substrate 252, the control system 190 can adjust the scan velocity in order to achieve an appropriate beam dwell time to treat different regions of the substrate 252.

Alternatively, the process GCIB 128A may be scanned at a constant velocity in a fixed pattern across the surface of the substrate 252; however, the GCIB intensity is modulated (may be referred to as Z-axis modulation) to deliver an intentionally non-uniform dose to the sample. The GCIB intensity may be modulated in the GCIB processing system 200 by any of a variety of methods, including varying the gas flow from a GCIB source supply; modulating the ionizer 122 by either varying a filament voltage V_{F} or varying an anode voltage V_{A}; modulating the lens focus by varying lens voltages V_{L1} and/or V_{L2}; or mechanically blocking a portion of the gas cluster ion beam with a variable beam block, adjustable shutter, or variable aperture. The modulating variations may be continuous analog variations or may be time modulated switching or gating.

The processing chamber 108 may further include an in-situ metrology system. For example, the in-situ metrology system may include an optical diagnostic system having an optical transmitter 280 and optical receiver 282 configured to illuminate substrate 252 with an incident optical signal 284 and to receive a scattered optical signal 288 from substrate 252, respectively. The optical diagnostic system comprises optical windows to permit the passage of the incident optical signal 284 and the scattered optical signal 288 into and out of the processing chamber 108. Furthermore, the optical transmitter 280 and the optical receiver 282 may comprise transmitting and receiving optics, respectively. The optical transmitter 280 receives, and is responsive to, controlling electrical signals from the control system 190. The optical receiver 282 returns measurement signals to the control system 190.

The in-situ metrology system may comprise any instrument configured to monitor the progress of the GCIB processing. According to one embodiment, the in-situ metrology system may constitute an optical scatterometry system. The scatterometry system may include a scatterometer, incorporating beam profile ellipsometry (ellipsometer) and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035).

For instance, the in-situ metrology system may include an integrated Optical Digital Profilometry (iODP) scatterometry module configured to measure process performance data resulting from the execution of a treatment process in the GCIB processing system 200. The metrology system may, for example, measure or monitor metrology data resulting from the treatment process. The metrology data can, for example, be utilized to determine process performance data that characterizes the treatment process, such as a process rate, a relative process rate, a feature profile angle, a critical dimension, a feature thickness or depth, a feature shape, etc. For example, in a process for directionally depositing material on a substrate, process performance data can include a critical dimension (CD), such as a top, middle or bottom CD in a feature (i.e., via, line, etc.), a feature depth, a material thickness, a sidewall angle, a sidewall shape, a deposition rate, a relative deposition rate, a spatial distribution of any parameter thereof, a parameter to characterize the uniformity of any spatial distribution thereof, etc. Operating the X-Y positioning table 253 via control signals from control system 190, the in-situ metrology system can map one or more characteristics of the substrate 252.

Control system 190 comprises a microprocessor, memory, and a digital I/O port capable of generating control voltages sufficient to communicate and activate inputs to GCIB processing system 100 (or 200) a as well as monitor outputs from GCIB processing system 100 (or 200). Moreover, control system 190 can be coupled to and can exchange information with vacuum pumping systems 170A, 170B, and 170C, first gas source 111, second gas source 112, first gas control valve 113A, second gas control valve 113B, beam electronics 130, beam filter 146, beam gate 148, the X-scan actuator 160, the Y-scan actuator 162, and beam current sensor 180. For example, a program stored in the memory can be utilized to activate the inputs to the aforementioned components of GCIB processing system 100 according to a process recipe in order to perform a GCIB process on substrate 152.

However, the control system 190 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The control system 190 can be used to configure any number of processing elements, as described above, and the control system 190 can collect, provide, process, store, and display data from processing elements. The control system 190 can include a number of applications, as well as a number of controllers, for controlling one or more of the processing elements. For example, control system 190 can include a graphic user interface (GUI) component (not shown) that can provide interfaces that enable a user to monitor and/or control one or more processing elements.

Control system 190 can be locally located relative to the GCIB processing system 100 (or 200), or it can be remotely located relative to the GCIB processing system 100 (or 200). For example, control system 190 can exchange data with GCIB processing system 100 using a direct connection, an intranet, and/or the internet. Control system 190 can be coupled to an intranet at, for example, a customer site (i.e., a device maker, etc.), or it can be coupled to an intranet at, for example, a vendor site (i.e., an equipment manufacturer). Alternatively or additionally, control system 190 can be coupled to the internet. Furthermore, another computer (i.e., controller, server, etc.) can access control system 190 to exchange data via a direct connection, an intranet, and/or the internet.

Substrate 152 (or 252) can be affixed to the substrate holder 150 (or substrate holder 250) via a clamping system (not shown), such as a mechanical clamping system or an electrical clamping system (e.g., an electrostatic clamping system). Furthermore, substrate holder 150 (or 250) can include a heating system (not shown) or a cooling system (not shown) that is configured to adjust and/or control the temperature of substrate holder 150 (or 250) and substrate 152 (or 252).

Vacuum pumping systems 170A, 170B, and 170C can include turbo-molecular vacuum pumps (TMP) capable of pumping speeds up to about 5000 liters per second (and greater) and a gate valve for throttling the chamber pressure. In conventional vacuum processing devices, a 1000 to 3000 liter per second TMP can be employed. TMPs are useful for low pressure processing, typically less than about 50 mTorr. Furthermore, a device for monitoring chamber pressure (not shown) can be coupled to the vacuum vessel 102 or any of the three vacuum chambers 104, 106, 108. The pressure-measuring device can be, for example, a capacitance manometer or ionization gauge.

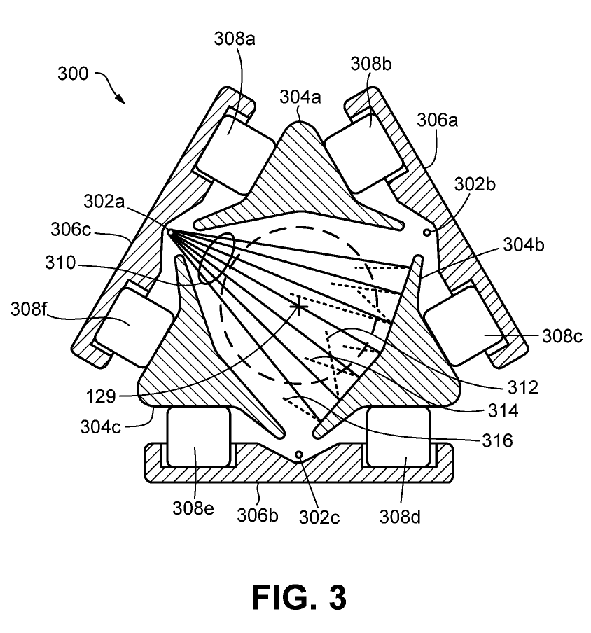

Referring now to FIG. 3, a section 300 of a gas cluster ionizer (122, FIGS. 1 and 2) for ionizing a gas cluster jet (gas cluster beam 118, FIGS. 1 and 2) is shown. The section 300 is normal to the axis of GCIB 128. For typical gas cluster sizes (2000 to 15000 atoms), clusters leaving the skimmer aperture (120, FIGS. 1 and 2) and entering an ionizer (122, FIGS. 1 and 2) will travel with a kinetic energy of about 130 to 1000 electron volts (eV). At these low energies, any departure from space charge neutrality within the ionizer 122 will result in a rapid dispersion of the jet with a significant loss of beam current. FIG. 3 illustrates a self-neutralizing ionizer. As with other ionizers, gas clusters are ionized by electron impact. In this design, thermo-electrons (seven examples indicated by 310) are emitted from multiple linear thermionic filaments 302a, 302b, and 302c (typically tungsten) and are extracted and focused by the action of suitable electric fields provided by electron-repeller electrodes 306a, 306b, and 306c and beam-forming electrodes 304a, 304b, and 304c. Thermo-electrons 310 pass through the gas cluster jet and the jet axis and then strike the opposite beam-forming electrode 304b to produce low energy secondary electrons (312, 314, and 316 indicated for examples).

Though (for simplicity) not shown, linear thermionic filaments 302b and 302c also produce thermo-electrons that subsequently produce low energy secondary electrons. All the secondary electrons help ensure that the ionized cluster jet remains space charge neutral by providing low energy electrons that can be attracted into the positively ionized gas cluster jet as required to maintain space charge neutrality. Beam-forming electrodes 304a, 304b, and 304c are biased positively with respect to linear thermionic filaments 302a, 302b, and 302c and electron-repeller electrodes 306a, 306b, and 306c are negatively biased with respect to linear thermionic filaments 302a, 302b, and 302c. Insulators 308a, 308b, 308c, 308d, 308e, and 308f electrically insulate and support electrodes 304a, 304b, 304c, 306a, 306b, and 306c. For example, this self-neutralizing ionizer is effective and achieves over 1000 micro Amps argon GCIBs.

Alternatively, ionizers may use electron extraction from plasma to ionize clusters. The geometry of these ionizers is quite different from the three filament ionizer described here but the principles of operation and the ionizer control are very similar.

According to an embodiment, a GCIB is utilized to deposit material on a surface of a substrate. For example, the GCIB can be provided using either of the GCIB processing systems (100 or 200, or combinations thereof) depicted in FIGS. 1 and 2. By adjusting the orientation of the substrate relative to the GCIB, material deposition can proceed on surfaces that are substantially perpendicular to the incident GCIB while material deposition can be avoided or reduced on surfaces that are substantially parallel with the incident GCIB. Moreover, one or more properties of the GCIB, including the beam composition, can be adjusted or alternated in order to directionally deposit successive material films having differing properties from one layer to an adjacent layer.

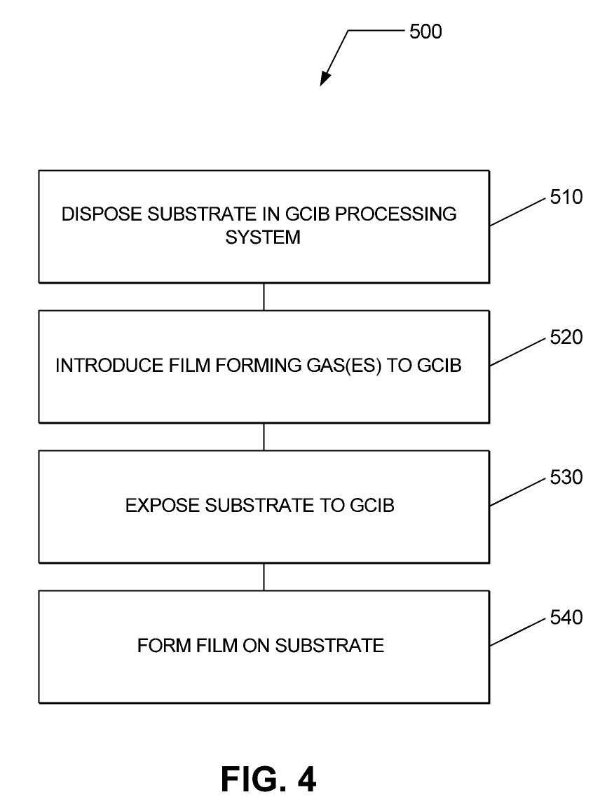

Referring to FIG. 4, a method of depositing material on a substrate using a GCIB is illustrated according to an embodiment. The method comprises a flow chart 500 beginning in 510 with disposing a substrate in a GCIB processing system. The substrate can be positioned on a substrate holder and may be securely held by the substrate holder. The temperature of the substrate may or may not be controlled. For example, the substrate may be heated or cooled during a film forming process. The environment surrounding the substrate is maintained at a reduced pressure, while a GCIB is formed from a pressurized gas mixture comprising one or more film forming species. The GCIB processing system can be any of the GCIB processing systems (100 or 200) described above in FIG. 1 or 2, or any combination thereof. The substrate can include a conductive material, a non-conductive material, or a semi-conductive material, or a combination of two or more materials thereof. Additionally, the substrate may include one or more material structures formed thereon, or the substrate may be a blanket substrate free of material structures.

In 520, film forming gas comprising one or more source gases is introduced to the GCIB to produce a film-forming GCIB. As described above, a pressurized gas is expanded into a reduced pressure environment to form gas-clusters, the gas-clusters are ionized, and the ionized gas-clusters are accelerated and optionally filtered.

The pressurized gas comprises a compound having silicon (Si) and carbon (C). The compound contains Si and C in the same molecule. Further, the compound may possess a Si—C bond. For example, the pressurized gas may comprise an alkyl silane, an alkane silane, an alkene silane, or an alkyne silane, or any combination of two or more thereof. Additionally, for example, the pressurized gas may include methylsilane (H₃C—SiH₃), dimethylsilane (H₃C—SiH₂—CH₃), trimethylsilane ((CH₃)₃—SiH), or tetramethylsilane ((CH₃)₄—Si), or any combination of two or more thereof. Several chemical formulations are provided below to illustrate the Si—C bond.

### METHYLSILANE

H₃C—SiH₃

### DIMETHYLSILANE

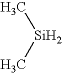

### TRIMETHYLSILANE

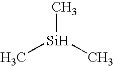

Additionally, for example, the pressurized gas may further include ethylsilane, diethylsilane, triethylsilane, or tetraethylsilane, or any combination of two or more thereof.

The pressurized gas may further comprise an inert gas, such as a noble gas.

Additionally, the pressurized gas may further comprise a nitrogen-containing gas. For example, the nitrogen-containing gas may include N₂, NH₃, NF₃, NO, N₂O, or NO₂, or a combination of two or more thereof. The addition of a nitrogen-containing gas may permit forming a silicon carbonitride film (SiCN) with relatively high carbon content.

Additionally yet, the pressurized gas may further comprise another carbon-containing gas. For example, another carbon-containing gas may include CO, CO₂, a hydrocarbon-containing gas, a fluorocarbon-containing gas, or a hydrofluorocarbon-containing gas, or any combination of two or more thereof.

Furthermore, the pressurized gas may further comprise an oxygen-containing gas or a hydrogen-containing gas or both.

In 530, the substrate is exposed to the film-forming GCIB. The film-forming GCIB may be scanned onto at least a portion of the surface of the substrate. Additionally, the GCIB dose may be adjusted as a function of position on the surface of the substrate in order to vary the thickness of the film formed on the surface of the substrate. The desired thickness of the film that is formed on the surface is achieved by selecting a GCIB dose. Furthermore, the orientation of the surface of the substrate relative to the GCIB may be adjusted.

In 540, a film is formed on the substrate, and the impact of multiple gas clusters on one or more surfaces on the substrate cause the formation of a deposited layer. As the gas clusters collide with the surface of the substrate, material is infused in the surface layer of the substrate or the underlying layer formed on the substrate. As the GCIB dose is increased, the infusion of material transitions to the deposition of material on the surface of the substrate.

The deposited layer comprises a film containing silicon and carbon, wherein the carbon content is greater than or equal to about 10%. Additionally, the carbon content may be greater than about 20%. Further, the carbon content may be greater than about 30%.

The beam energy may be greater than about 30 keV. Alternatively, the beam energy may be greater than about 10 keV. Alternatively yet, the beam energy may be greater than about 5 keV. Alternately yet, the beam energy may be greater than about 1 keV. For example, the beam energy may range from about 1 keV to about 70 keV.

Once the film is deposited, the method may further comprise exposing the film to one or more thermal cycles, or annealing the film.

According to an example, a silicon carbide-containing film is prepared using two different pressurized source gases. The first silicon carbide-containing film is prepared with a GCIB using silane (SiH₄) and methane (CH₄) as a film-forming precursor. The second silicon carbide-containing film is prepared with a GCIB using methylsilane as a film-forming precursor. Table 1 provides the elemental composition of each film as determined by X-ray photoelectron spectroscopy (XPS). Each film is irradiated with X-rays, and a spectrum having a series of photoelectron peaks is acquired by measuring the energy of the emitted electrons, wherein the binding energy of the peaks are characteristic of each element present in the film.

TABLE 1

| Source | | Film composition | Carbon | Carbon content |
|---|---|---|---|---|
| gas(es) | Element | (%) | bond | (%) |
| SiH₄ + CH₄ | C | 5.3 | SiC | 56 |
| | Si | 84.5 | C—C, C—H | 42 |
| | O | 10.2 | C—O | 2 |
| H₃C—SiH₃ | C | 39.7 | SiC | 86 |
| | Si | 52.7 | C—C, C—H | 11 |
| | O | 5.6 | graphitic | 3 |

The inventors have discovered that using a pressurized source gas comprising a compound having silicon (Si) and carbon (C) can lead to a substantial increase in the carbon content in a GCIB deposited film (e.g., about an order of magnitude increase). Moreover, the inventors have discovered that using this source gas can lead to a substantial increase in the SiC content in the GCIB deposited film (e.g., more than an order of magnitude increase).

As shown in Table 1, the first film, prepared using silane (SiH₄) and methane (CH₄) as the source gases, comprises a carbon content of approximately 5%. Therein, about 56% of the carbon content is bonded to silicon (Si) as SiC. Therefore, about 3% of the material deposited in the first film is C bonded to Si as SiC. Furthermore, about 3% (not shown) of the material is Si bonded to C as SiC. As a result, about 6% of the total composition of the material in the first film is silicon carbide (SiC).

Further, as shown in Table 1, the second film, prepared using dimethylsilane as the source gas, comprises a carbon content of approximately 39.7%. Therein, about 86% of the carbon content is bonded to silicon (Si) as SiC. Therefore, about 34% of the material deposited in the second film is C bonded to Si as SiC. Furthermore, about 34% (not shown) of the material is Si bonded to C as SiC. As a result, about 68% of the total composition of the material in the first film is silicon carbide (SiC).

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method for depositing a thin film at a surface on a substrate, comprising:
maintaining a reduced-pressure environment around a substrate holder for holding a substrate having a surface;
holding said substrate securely within said reduced-pressure environment;
forming a gas cluster ion beam (GCIB) from a pressurized gas comprising a compound having silicon (Si) and carbon (C);
accelerating said GCIB to said reduced-pressure environment; and
irradiating said accelerated GCIB onto at least a portion of said surface of said substrate to form a thin film containing silicon and carbon, wherein the carbon content is greater than or equal to about 10%.

2. The method of claim 1, wherein said compound further comprises a Si—C bond.

3. The method of claim 2, wherein said compound having silicon (Si), carbon (C) and a Si—C bond comprises an alkyl silane.

4. The method of claim 2, wherein said compound having silicon (Si), carbon (C) and a Si—C bond comprises an alkane silane, an alkene silane, or an alkyne silane.

5. The method of claim 2, wherein said compound having silicon (Si), carbon (C) and a Si—C bond comprises methylsilane, dimethylsilane, trimethylsilane, tetramethylsilane, ethylsilane, diethylsilane, triethylsilane, or tetraethylsilane.

6. The method of claim 2, wherein said compound having silicon (Si), carbon (C) and a Si—C bond consists of methylsilane.

7. The method of claim 1, wherein the carbon content is greater than or equal to about 20%.

8. The method of claim 1, wherein the carbon content is greater than or equal to about 30%.

9. The method of claim 1, wherein said pressurized gas further comprises a nitrogen-containing gas.

10. The method of claim 9, wherein said pressurized gas further comprises N₂, NH₃, NF₃, NO, N₂O, or NO₂, or a combination of two or more thereof.

11. The method of claim 1, wherein said pressurized gas further comprises a noble gas.

12. The method of claim 1, wherein said pressurized gas further comprises another carbon-containing gas.

13. The method of claim 12, wherein said another carbon-containing gas comprises CO, CO₂, a hydrocarbon-containing gas, a fluorocarbon-containing gas, or a hydrofluorocarbon-containing gas, or any combination of two or more thereof.

14. The method of claim 1, further comprising:
annealing said thin film.

15. The method of claim 1, wherein the gas-clusters of said GCIB are accelerated by an acceleration voltage between about 1 and 70 keV.

16. The method of claim 1, further comprising:
filtering said GCIB to substantially reduce the number of clusters having 100 or less atoms or molecules or both.

17. The method of claim 1, wherein the thickness of said thin film that is formed on said surface is achieved by selecting a GCIB dose.

18. The method of claim 17, wherein said irradiating comprises:
scanning said accelerated GCIB onto at least a portion of said surface of said substrate; and
adjusting the GCIB dose as a function of position on said surface of said substrate in order to vary the thickness of said thin film formed on said surface of said substrate.

19. The method of claim 1, further comprising:
adjusting the orientation of said surface of said substrate relative to said GCIB.

20. A computer readable medium containing program instructions for execution on a GCIB processing system, which when executed by the GCIB processing system, cause the GCIB processing system to perform the steps of:
maintaining a reduced-pressure environment around a substrate holder for holding a substrate having a surface;
holding said substrate securely within said reduced-pressure environment;
forming a gas cluster ion beam (GCIB) from a pressurized gas comprising a compound having silicon (Si) and carbon (C);
accelerating said GCIB to said reduced-pressure environment; and
irradiating said accelerated GCIB onto at least a portion of said surface of said substrate to form a thin film containing silicon and carbon, wherein the carbon content is greater than or equal to about 10%.
